(19) United States
(12) Patent Application Publication
(10) Pub. No.: US 2026/0152871 A1
(43) Pub. Date: Jun. 4, 2026

(54) MANUFACTURING METHOD FOR SEMICONDUCTOR DEVICE USING EPITAXY PROCESS AND APPARATUS FOR THE SAME

(71) Applicant: Viatron Technologies, Inc., Gyeonggi-do (KR)

(72) Inventors: Hyoung June Kim, Seoul (KR); Jae Sung Roh, Gyeonggi-do (KR); Wang Jun Park, Gyeonggi-do (KR); Jong Sik Kim, Seoul (KR)

(21) Appl. No.: 18/880,180

(22) PCT Filed: Nov. 4, 2022
(86) PCT No.: PCT/KR2022/017216

§ 371 Date: Aug. 18, 2025

(30) Foreign Application Priority Data
Jul. 1, 2022 (KR) 10-2022-0081473
Jul. 29, 2022 (KR) 10-2022-0094940

(51) Int. Cl. C30B 25/10; C23C 16/06; C23C 16/24; C23C 16/458; C23C 16/48; C30B 25/12; C30B 29/06; C30B 29/52; H10P 14/20

(52) U.S. Cl. CPC C30B 25/105; C23C 16/06; C23C 16/24; C23C 16/4583; C23C 16/481; C30B 25/12; C30B 29/06; C30B 29/52; H10P 14/3411

(57) ABSTRACT

The present invention discloses the manufacturing method for the semiconductor device comprising a first thin film deposition step of supplying a first source gas at a first deposition temperature to deposit the first thin film to the top surface of the flat substrate, a deposition temperature-lowering step of lowering a temperature of the flat substrate from the first deposition temperature to a second deposition temperature, a second thin film deposition step of supplying a second source gas at the second deposition temperature to deposit the second thin film to a top surface of the first thin film, and a deposition temperature-rising step of rising the temperature of the flat substrate from the second deposition temperature to the first deposition temperature, and discloses a semiconductor device manufacturing apparatus for the above method.

### TECHNICAL FIELD

The present invention relates to a manufacturing method for a semiconductor device using an epitaxy process, and a manufacturing apparatus therefor.

### BACKGROUND ART

Semiconductor devices, such as a Gate-All-Around (GAA) MOS device and a 3D DRAM, may be manufactured by forming a multi-layered thin film such as [Si/SiGeₓ]n. The semiconductor devices may be formed by an epitaxy process for depositing a multi-layered thin film in which a Si thin film and a SiGeₓ layer are alternately formed. The epitaxy process alternately repeats a Si thin film deposition process in which SiH₄ gas is supplied to deposit a Si thin film, and a SiGeₓ thin film deposition process in which SiH₄/GeH₄ gas is supplied to deposit a SiGeₓ thin film. Each of the deposition rate for the first thin film and the deposition rate for the second thin film may be increased as the deposition temperature is increased.

In addition, the deposition rate of the first thin film and the deposition rate of the second thin film may differ by several tens of times at the same deposition temperature. For example, when the Si thin film deposition process and the SiGeₓ thin film deposition process are performed at the same deposition temperature, the deposition rate of the Si thin film and the deposition rate of the SiGeₓ thin film differ by several tens of times. Therefore, when the deposition temperature is the same, the deposition time of the first (Si) thin film should be several tens of times longer than the deposition time of the second (SiGeₓ) thin film. For example, when the deposition temperature is 600° C., the deposition rate of the first thin film is 2 [symbol] /min, and the deposition rate of the second thin film is 50 [symbol] /min, so the deposition rate ratio is 25 times. When the deposition temperature is 600° C. and a thickness of the thin film is 50 [symbol] , the deposition of the first thin film takes 25 minutes, and the deposition of the second thin film takes 1 minute. Therefore, the production efficiency may be decreased as the total deposition time required to deposit the first and second thin films is increased.

### DISCLOSURE OF THE INVENTION

### TECHNICAL PROBLEM

The purpose of the present invention is to provide a manufacturing method for a semiconductor device using an epitaxy process capable of increasing a deposition rate and a deposition efficiency of a multi-layered thin film constituting a semiconductor device, and a manufacturing apparatus therefor.

### TECHNICAL SOLUTION

A method of the present invention includes heating a flat substrate with a VCSEL device and forming a multi-layered thin film (in which a first thin film and a second thin film are alternately deposited) on a top surface of the flat substrate through an epitaxy process, the manufacturing method for the semiconductor device may further includes a first thin film deposition step of supplying a first source gas at a first deposition temperature to deposit the first thin film to the top surface of the flat substrate, a deposition temperature-lowering step of lowering a temperature of the flat substrate from the first deposition temperature to a second deposition temperature, a second thin film deposition step of supplying a second source gas at the second deposition temperature to deposit the second thin film to a top surface of the first thin film, and a deposition temperature-rising step of rising the temperature of the flat substrate from the second deposition temperature to the first deposition temperature. At this time, the first thin film may be Si thin film, and the second thin film may be SiGeₓ(0.1<x<0.4) thin film.

Also, the first deposition temperature may be 600 to 800° C., the second deposition temperature may be 500 to 750° C., the time for lowering the deposition temperature in the deposition temperature-lowering step may be 1 to 10 seconds, and the time for rising the deposition temperature in the deposition temperature-rising step may be 1 to 5 seconds

In addition, the first deposition temperature and the second deposition temperature may be set such that the first deposition rate of the first thin film is 0.1 to 2 times the second deposition rate of the second thin film.

Furthermore, in the first thin film deposition step and the second thin film deposition step, the first deposition temperature and the second deposition temperature may be controlled such that the uniformity is 0.2% or less.

Also, a periphery of the flat substrate may be supported such that a lower surface thereof is exposed, a laser beam irradiated from the VCSEL device may be directly irradiated to the lower surface of the flat substrate, and the flat substrate may be rotated when the laser beam is irradiated.

In addition, in the semiconductor device manufacturing method, a substrate heating unit including the VCSEL device irradiating the laser beam for heating the flat substrate may be used, the substrate heating unit has a VCSEL module formed by combining at least two VCSEL sub-modules having an device region on which the at least two VCSEL devices are arranged and a terminal region on which terminals for supplying power to the VCSEL devices may be arranged, the VCSEL module may be arranged on an area larger than an area of the flat substrate, and a separation distance between the VCSEL module and the flat substrate may be 100 to 300 [symbol] .

Furthermore, the VCSEL sub-modules of the VCSEL module may be arranged such that the terminal regions of the VCSEL sub-modules are linearly connected to each other in one direction.

Also, the VCSEL module may irradiate a laser beam such that the temperature of the flat substrate has a temperature uniformity of 0.2% or less, the VCSEL device may have a maximum separation distance of the micro-emitter array of 0.1 [symbol] and a size of the electrode region smaller than 0.1 [symbol] , the VCSEL sub-module may have a separation distance of the VCSEL devices smaller than 1 [symbol] , and the VCSEL module may be arranged such that the separation distance of the VCSEL sub-modules is smaller than 10 [symbol] .

In addition, the VCSEL sub-modules may be independently supplied with power, and light emitting intensities of the VCSEL sub-modules may be individually controlled such that the flat substrate is heated to a predetermined deposition temperature using a pyrometer detecting the temperature of the flat substrate below the flat substrate.

Furthermore, the flat substrate is rotated by a magnetic levitation method, and the flat substrate is rotated without interference from the VCSEL module during rotation.

A semiconductor device manufacturing apparatus of the present invention using an epitaxy process is provided to perform the manufacturing method for the semiconductor device defined as above, this apparatus is characterized in that a substrate heating unit including the VCSEL device irradiating the laser beam for heating a flat substrate is used, the substrate heating unit has a VCSEL module formed by combining at least two VCSEL sub-modules having an device region on which the at least two VCSEL devices are arranged and a terminal region on which terminals for supplying power to the VCSEL devices are arranged, the VCSEL module is arranged on an area larger than an area of the flat substrate, and a separation distance between the VCSEL module and the flat substrate is 100 to 300 [symbol] .

Also, the VCSEL sub-modules of the VCSEL module may be arranged such that the terminal regions of the VCSEL sub-modules are linearly connected to each other in one direction.

In addition, the VCSEL module may irradiate a laser beam such that the temperature of the flat substrate has a temperature uniformity of 0.2% or less, the VCSEL device may have a maximum separation distance of the micro-emitter array of 0.1 [symbol] and a size of the electrode region smaller than 0.1 [symbol] , the VCSEL sub-module may have a separation distance of the VCSEL devices smaller than 1 [symbol] , and the VCSEL module may be arranged such that the separation distance of the VCSEL sub-modules is smaller than 10 [symbol] .

Furthermore, the VCSEL sub-modules may be independently supplied with power, and light emitting intensities of the VCSEL sub-modules may be individually controlled such that the flat substrate is heated to a predetermined deposition temperature using a pyrometer detecting the temperature of the flat substrate below the flat substrate.

Also, the flat substrate may be rotated by a magnetic levitation method, and the flat substrate may be rotated without interference from the VCSEL module during rotation.

### ADVANTAGEOUS EFFECTS

The manufacturing method for the semiconductor device of the present invention using the epitaxy process and the semiconductor device manufacturing apparatus for the above method can increase the deposition rate and deposition efficiency of the multi-layered thin film in a process of manufacturing the multi-layered thin film constituting the semiconductor device using the epitaxy process.

### BRIEF DESCRIPTION OF THE DRAWINGS

FIG. 1 is a process diagram of a manufacturing method for a semiconductor device using an epitaxy process, according to one embodiment of the present invention;

FIG. 2 is a graph for deposition rates of a first thin film and a second thin film in an epitaxy process, according to temperatures;

FIG. 3 is a vertical cross-sectional view of a semiconductor device manufacturing apparatus for the semiconductor manufacturing method of FIG. 1;

FIG. 4 is a plan view of a substrate-heating unit of FIG. 3;

FIG. 5 is a partial perspective view of the substrate-heating unit of FIG. 3;

FIG. 6 is a graph showing temperature uniformity according to a separation distance between a wafer and a VCSEL module;

FIG. 7 is a graph showing a temperature of the wafer measured when a wafer is being heated while increasing power applied to the VCSEL module; and

FIG. 8 is a graph showing temperature-variable characteristics of the wafer when the wafer is heated and cooled with the VCSEL module.

### BEST MODE FOR CARRYING OUT THE INVENTION

Hereinafter, a manufacturing method for a semiconductor device using an epitaxy process of the present invention and a manufacturing apparatus therefor will be described in more detail through embodiments and the attached drawings.

First manufacturing method for a semiconductor device using an epitaxy process according to one embodiment of the present invention will be described.

FIG. 1 is a process diagram of a manufacturing method for a semiconductor device using an epitaxy process, according to one embodiment of the present invention, and

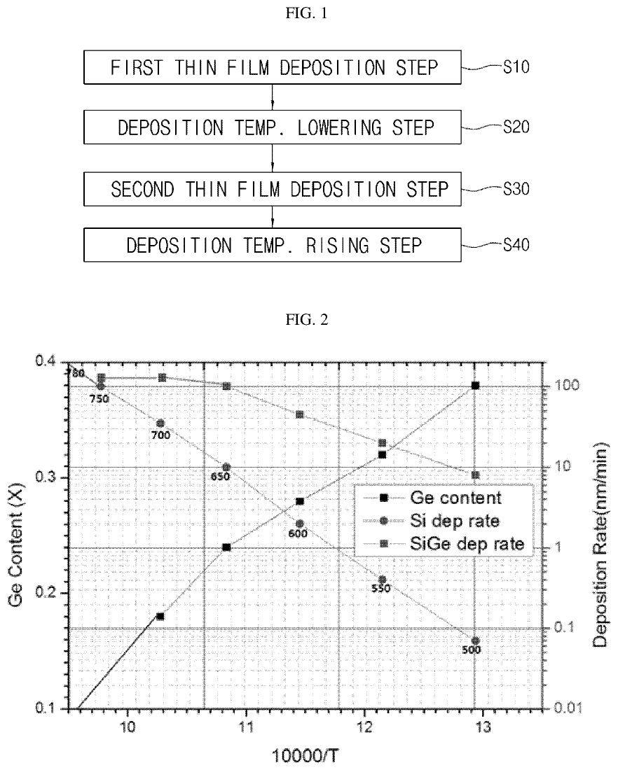

FIG. 2 is a graph for deposition rates of a first thin film and a second thin film in the epitaxy process, according to temperatures.

Referring to FIG. 1, a manufacturing method for a semiconductor device using an epitaxy process, according to one embodiment of the present invention may include a first thin film deposition step S10, a deposition temperature-lowering step S20, a second thin film deposition step S30, and a deposition temperature-rising step S40.

The manufacturing method for the semiconductor device may be employed in a method for fabricating a semiconductor device including a multi-layered thin film in which a first thin film and a second thin film are alternately laminated. Here, the first thin film and the second thin film may be thin films which have different deposition rates under the same deposition temperature when deposited by an epitaxy process. At the same deposition temperature, the first thin film may have a relatively low deposition rate and the second thin film may have a relatively high deposition rate. In addition, the deposition rates of the first thin film and the second thin film may be decreased as the deposition temperature is decreased. The degree to which the deposition rate of the first thin film is decreased may be greater than the degree to which the deposition rate of the second thin film is decreased. Meanwhile, in the semiconductor device manufacturing method, when the deposition rates of the first thin film and the second thin film are opposite to the above, the deposition temperature-lowering step S20 and the deposition temperature-rising step S40 may be performed in reverse.

The manufacturing method for the semiconductor device may be used to fabricate a multi-layered thin film of [Si/SiGeₓ]n (where, n is 1 or more). In this case, the first thin film may be a Si thin film. In addition, the second thin film may be a SiGeₓ thin film. Here, x may be in 0.1<x<0.40. In addition, x may preferably be in 0.25<x<0.38. At this time, the SiGeₓ thin film may be a thin film formed in a process of manufacturing a Gate-All-Around (GAA) MOS device. That is, the manufacturing method for the semiconductor device may be a method of manufacturing the Gate-All-Around (GAA) MOS device. Furthermore, x may preferably be in 0.15<x<0.25. At this time, the SiGeₓ thin film may be a thin film formed in a process of manufacturing a 3D DRAM. That is, the manufacturing method for the semiconductor device may be a method for manufacturing the 3D DRAM. In addition, the first thin film may be formed by supplying a first source gas. In addition, the second thin film may be formed by supplying a second source gas. At this time, the second source gas may be a mixed gas of the first source gas and GeH₄.

The semiconductor device may be a semiconductor device such as the Gate-All-Around (GAA) MOS device and the 3D DRAM. In addition to the multi-layered thin film of [Si/SiGeₓ]n, the semiconductor device may further include a configuration such as various thin films, or electrically-conductive wired patterns through which current flows, depending on the type of the device. The manufacturing method for the semiconductor device may further include various processes necessary for forming additional configurations of the semiconductor device.

In addition, the manufacturing method for the semiconductor device of the present invention may be applied to various processes for forming at least two thin films having different deposition rates at one deposition temperature other than the epitaxy process. In addition, the manufacturing method for the semiconductor device may also be applied to a process for forming at least two thin films having the same or different deposition rates at different temperatures and a case of heat-treating the deposited thin film. For example, the manufacturing method for the semiconductor device may also be applied to processes such as a semiconductor dopant activation rapid thermal treatment process, a silicide rapid thermal treatment process, a chemical vapor deposition process (CVD), or an atomic layer deposition process (ALD).

In addition, the manufacturing method for the semiconductor device of the present invention may increase the deposition rate of the thin film by varying the deposition temperature for each thin film. In addition, the manufacturing method for the semiconductor device may increase the deposition rate of [Si/SiGeₓ]n multi-layered thin film by relatively shortening the time for lowering the deposition temperature and the time for rising the deposition temperature. As mentioned above, the conventional epitaxy equipment may require the time for lowering the deposition temperature and the time for rising the deposition temperature of about 90 to 150 seconds. In comparison, in the semiconductor device manufacturing method, it may take a time of 1 to 5 seconds to lower the deposition temperature and a time of 1 to 2 second to rise the deposition temperature, respectively.

The manufacturing method for the semiconductor device may be performed while continuously supplying the first source gas, since the time for lowering the deposition temperature and the time for rising the deposition temperature are relatively shortened. That is, the deposition temperature-lowering step S20 and the deposition temperature-rising step S40 may be performed in a state where the first source gas is being supplied. Therefore, since the deposition temperature-lowering step S20 and the deposition temperature-rising step S40 are performed in a state where the first source gas is being supplied, it is possible to stably maintain an atmosphere in which the deposition is performed. Generally, the deposition temperature-lowering step S20 and the deposition temperature-rising step S40 are performed in a state where the first source gas is not supplied.

The manufacturing method for the semiconductor device may employ a VCSEL device as a heating means for heating a flat substrate or a deposited thin film. The heating means may be formed by arranging the VCSEL devices in an area corresponding to or larger than an area of the flat substrate. By irradiating a laser beam emitted from the VCSEL device a lower surface of the flat substrate, the heating means may heat the flat substrate. The manufacturing method for the semiconductor device may support a periphery of the flat substrate without using a separate susceptor and may be performed in a state where the lower surface of the flat substrate is exposed. In addition, the manufacturing method for the semiconductor device may be performed while rotating the flat substrate. Therefore, in the semiconductor device manufacturing method, it is possible to control a deviation in temperature between a first deposition temperature and a second deposition temperature in the epitaxy process to 0.2% or less.

The flat substrate may be a wafer or a glass substrate. In addition, the flat substrate may be a flexible substrate such as a resin film. Also, the flat substrate may include various elements or electrically-conductive wired patterns formed on a surface or inside thereof.

The first thin film deposition step S10 is a step of supplying the first source gas at the first deposition temperature to deposit the first thin film on an upper side of the flat substrate. The first thin film deposition step S10 is a step of depositing the first thin film by the epitaxy process. The first thin film may be deposited on the upper portion of the flat substrate in a first cycle, and may be deposited on an upper side of the second thin film from a second cycle or onward. In addition, the first thin film may be deposited on an upper side of another thin film deposited on the flat substrate or the upper side of the second thin film. Here, the first thin film may be a Si thin film. The first source gas may be one gas selected from Si₂H₂Cl₂, SiH₄, Si₂H₆ and Si₃H₈, or a mixed gas of at least two gases.

In the first thin film deposition step S10, the first deposition temperature may be controlled based on a surface temperature of the flat substrate. In addition, in the first thin film deposition step S10, it is possible to control the first deposition temperature such that the uniformity is in a range of 0.2% or less. To this end, the first thin film deposition step S10 is performed while a VCSEL device of a substrate heating means is employed as a light source of laser beam to heat the flat substrate and the flat substrate is rotated using a substrate rotating means. In addition, in the first thin film deposition step S10, the heating means may irradiate the laser beam of the VCSEL device directly to a lower surface of the flat substrate without placing the flat substrate on a separate susceptor and heat the flat substrate. The first deposition temperature may be 600 to 800° C. In addition, the first deposition temperature may preferably be 650 to 750° C. At this time, Si may be a thin film formed in the process of manufacturing a Gate-All-Around (GAA) MOS device. That is, the manufacturing method for the semiconductor device may be a method of manufacturing the Gate-All-Around (GAA) MOS device. Furthermore, the first deposition temperature may preferably be 700 to 800° C. At this time, Si may be a thin film formed during the process of manufacturing a 3D DRAM. That is, the manufacturing method for the semiconductor device may be a method of manufacturing a 3D DRAM. Here, the first deposition temperature may be a surface temperature of the flat substrate, the second film or the first film which is being deposited.

The first thin film deposition step S10 may be configured to deposit the first thin film at a first deposition rate. The first deposition rate may be 1 to 150 [symbol] /min. In addition, the first deposition rate may be preferably 10 to 100 [symbol] /min. At this time, the first deposition rate may be a rate at which a thin film is deposited in a process of manufacturing the Gate-All-Around (GAA) MOS device. In addition, the first deposition rate may be preferably 35 to 150 [symbol] /min. At this time, the first deposition rate may be a rate at which a thin film is deposited in a process of manufacturing the 3D DRAM. The first thin film deposition step S10 may be performed under a reduced pressure condition where a process pressure of a process chamber is 0.1 to 500 Torr.

The deposition temperature-lowering step S20 is a step of lowering the temperature of the flat substrate from the first deposition temperature to the second deposition temperature. The second deposition temperature is a temperature lower than the first deposition temperature. The second deposition temperature is a temperature at which the epitaxy process for depositing the second thin film is performed. The second deposition temperature may be 500 to 750° C. In addition, the second deposition temperature may preferably be 500 to 650° C. At this time, the second deposition temperature may be a temperature at which SiGeₓ thin film is formed as the second thin film. In addition, the SiGeₓ thin film may be a thin film formed in the process of manufacturing the Gate-All-Around (GAA) MOS device. That is, the manufacturing method for the semiconductor device may be a method for manufacturing the Gate-All-Around (GAA) MOS device. In addition, the second deposition temperature may preferably be 630 to 730° C. At this time, the SiGe x thin film may be a thin film formed in the process of manufacturing the 3D DRAM. That is, the manufacturing method for the semiconductor device may be a method of manufacturing the 3D DRAM. Here, the second deposition temperature may be the surface temperature of the flat substrate, the first thin film, or the second thin film.

The deposition temperature-lowering step S20 may be performed for a predetermined deposition temperature lowering time. That is, the deposition temperature lowering time is the time required to lower the first deposition temperature to the second deposition temperature. The deposition temperature lowering time may be 1 to 10 seconds. In addition, the deposition temperature lowering time may be preferably 1 to 5 seconds. The deposition temperature-lowering step S20 may lower the deposition temperature for a deposition temperature lowering time shorter than a time required for temperature change in a conventional epitaxy equipment. It has been known that the conventional epitaxy equipment takes approximately 90 to 150 seconds to lower the temperature by 50 to 250° C. The deposition temperature-lowering step S20 may lower the deposition temperature for a relatively short time, while preventing the flat substrate or the thin films from being underheated below the deposition temperature.

The deposition temperature-lowering step S20 may be performed in a state in which the first source gas is being supplied. Since the deposition temperature-lowering step S20 is performed for a relatively short time compared to an existing method, even if the first source gas is supplied, the consumption amount of gas may not be large. In addition, since the deposition temperature-lowering step S20 is performed in a state in which the first source gas is being supplied, the atmosphere in which the deposition is performed may be stably maintained.

The second thin film deposition step S30 is a step of supplying the second source gas at the second deposition temperature to deposit the second thin film on an upper side of the first thin film. The second thin film deposition step S30 is a step of depositing the second thin film using an epitaxy process. The second thin film deposition step S30 may control the second deposition temperature based on the surface temperature of the flat substrate. The second thin film deposition step S30 may control the second deposition temperature within a uniformity range of 0.2% or less. To this end, the second thin film deposition step S30 is performed while the VCSEL device of the substrate heating means is employed as a light source of laser beam and the flat substrate is rotated. In addition, in the second thin film deposition step S30, the heating means may irradiate the laser beam of the VCSEL device directly to the lower surface of the flat substrate without placing the flat substrate on a separate susceptor and heat the flat substrate. The second deposition temperature may be 500 to 750° C. as mentioned above. In addition, the second deposition temperature may be preferably 500 to 650° C. Furthermore, the second deposition temperature may be preferably 630 to 730° C.

The second thin film may be a SiGeₓ thin film. Here, x may be 0.1<x<0.40 as mentioned above. In addition, x may be preferably 0.25<x<0.38. Furthermore, x may be preferably 0.15<x<0.25.

The second source gas may be a mixed gas of the first source gas and GeH₄. GeH₄ may be used as the source gas of Ge. The second thin film deposition step S30 may deposit the second thin film at a second deposition rate. The second deposition rate may be 10 to 120 [symbol] /min. The second thin film deposition step S30 may be performed under a reduced pressure condition where a process pressure of a process chamber is 0.1 to 500 Torr.

The deposition temperature-rising step S40 is a step of rising the temperature of the flat substrate from the second deposition temperature to the first deposition temperature.

The deposition temperature-rising step S40 may be performed for a predetermined deposition temperature rising time. That is, the deposition temperature-rising time is a time required to rise the second deposition temperature to the first deposition temperature. The deposition temperature-rising time may be 1 to 5 seconds. In addition, the deposition temperature-rising time may be 1 to 2 seconds. The deposition temperature-rising time may be a shorter than the deposition temperature-lowering time. For example, the deposition temperature-rising time may be 1.2 seconds, and the deposition temperature-lowering time may be 3.0 seconds. It has been known that the conventional epitaxy equipment takes approximately 90 to 150 seconds to lower the temperature by 50 to 250° C. The deposition temperature-rising step S40 may rise the deposition temperature for a relatively short time, while preventing the flat substrate or the thin films from being overheated above the deposition temperature.

The deposition temperature-rising step S40 may be performed in a state in which the first source gas is being supplied. Since the deposition temperature-rising step S40 is performed for a relatively short time compared to an existing method, even if the first source gas is supplied, the consumption amount of gas may not be large. In addition, since the deposition temperature-rising step S40 is performed in a state in which the first source gas is being supplied. the atmosphere in which the deposition is performed may be stably maintained.

The manufacturing method for the semiconductor device may set the first deposition temperature for depositing the first thin film and the second deposition temperature for depositing the second thin film differently. As shown in FIG. 2, the first thin film and the second thin film may have different deposition rates at the same deposition temperature. Therefore, the manufacturing method for the semiconductor device may set the first deposition temperature to be relatively higher than the second deposition temperature in order to increase the first deposition rate for depositing the first thin film. The manufacturing method for the semiconductor device may set the first deposition rate so that it is 0.1 to 2 times the second deposition rate.

A semiconductor device manufacturing apparatus for the manufacturing method for the semiconductor device according to one embodiment of the present invention is described below.

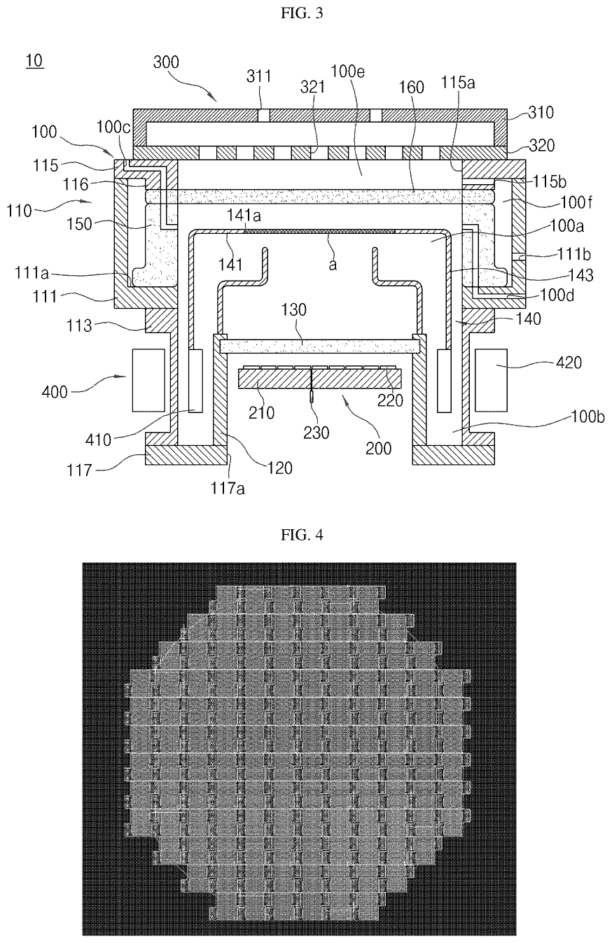

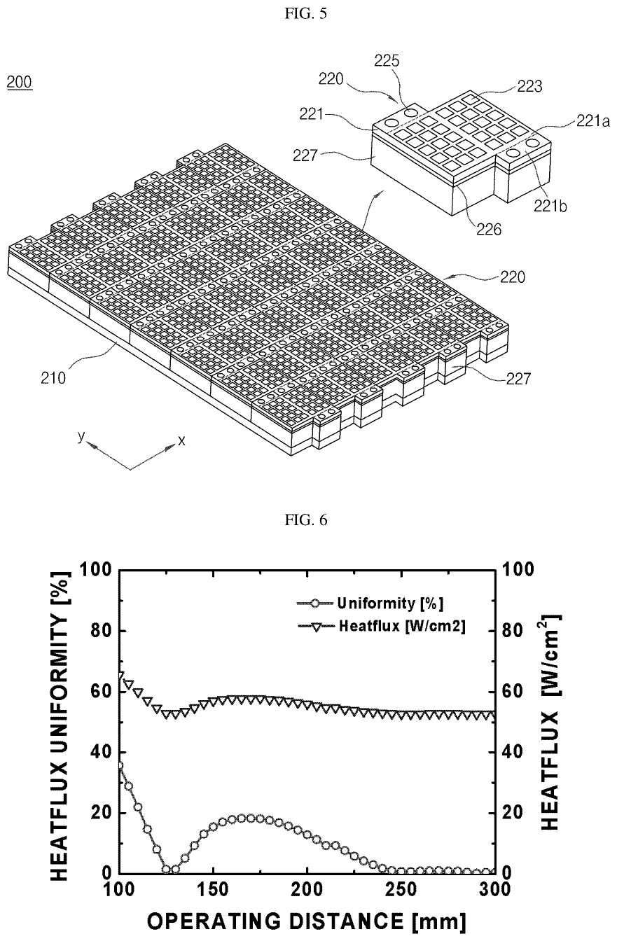

FIG. 3 is a vertical cross-sectional view of a semiconductor device manufacturing apparatus for the semiconductor manufacturing method of FIG. 1. FIG. 4 is a plan view of a substrate-heating unit of FIG. 3. FIG. 5 is a partial perspective view of the substrate-heating unit of FIG. 3.

Referring to FIGS. 3 to 5, a semiconductor device manufacturing apparatus 10 may include a process chamber 100, a substrate heating unit 200, a cooling gas injection unit 300, and a substrate rotating unit 400.

The semiconductor device manufacturing apparatus 10 may utilize a VCSEL device as a substrate heating means for heating a flat substrate a. The VCSEL device may irradiate a laser beam having a wavelength band of 1 [symbol] or less in order to heat a wafer, which is a flat substrate a, in the epitaxy process. Furthermore, the VCSEL device may irradiate a laser beam with a single wavelength of 1 [symbol] or less. For example, the VCSEL device may be a device that preferably irradiates a laser beam of a single wavelength of approximately 940 [symbol] .

The VCSEL device may be placed such that an entire region of the flat substrate a may be irradiated with a laser beam. The VCSEL device may heat the flat substrate a uniformly by utilizing radiation characteristics of the laser beam emitted from the micro-emitter and the characteristics of laser beam that overlaps with the laser beam of the adjacent micro-emitter. A radiation angle of the laser beam emitted from the micro-emitter is 20 to 30 degrees, and power of the laser beam may be transmitted to only a part of the wafer even at a separation distance of 100 [symbol] or more between the wafer and the VCSEL device. Therefore, by dividing and placing the VCSEL devices on the VCSEL sub-modules and configuring an independent power line that controls individual power for each sub-module, a zone control method, which controls power of the laser beam transmitted to the wafer from a zone to a zone, may be available. The semiconductor device manufacturing apparatus 10 may irradiate a laser beam irradiated from the substrate heating module to the flat substrate to heat the flat substrate.

On the other hand, the wafer used as the flat substrate (a) may absorb a laser beam having a wavelength of 1 [symbol] or less at 400° C. or higher. Therefore, as the substrate heating means, an LED light source having a wavelength band of R(0.8 [symbol] ), G(0.6 [symbol] ), B(0.4 [symbol] ) may be considered. However, the LED light source is a surface emitting light source, and has a light emitting characteristic by which the light radiates in a hemispherical omnidirectional manner. Due to characteristic of hemispherical radiation of the LED light source, in order to heat the wafer, the wafer and LED device must have a very small separation distance therebetween, less than 50 [symbol] . If the separation distance is small in the high temperature range of 400 to 1,000° C. which is the deposition temperature of the epitaxy process, thermal deterioration of the LED device cannot be avoided. Therefore, the LED light source may be applied only when the heating temperature of the wafer is 400° C. or lower.

In addition, due to characteristic of hemispherical radiation of the LED light source, the LED array having a large area or the entire LED array participates in heating for one point of the wafer. In order to precisely heat the wafer, a range of the LED array participating in a heating for the local region is limited, so it is very difficult to perform the zone control method, which individually controls output of the LED array of a zone participating in a heating for the local region. As the wafer heating method using the LED light source, a method of making the number density of the LED array different from a part to a part to achieve uniform light heating may be applied, but this method may not be suitable for use for precise temperature control of the epitaxy process.

During the semiconductor device manufacturing process, in addition, a halogen lamp is utilized a rapid thermal processing for activating the dopant of the thin film deposited on the wafer or forming silicide. The halogen lamp may directly irradiate an upper surface, a lower surface, or upper and lower surfaces of the wafer with a laser beam to rapidly heat and cool the wafer. However, the light irradiated from the halogen lamp has a wavelength spectrum with a peak near 1 [symbol] and has a wide distribution in the 0.5 to 3 [symbol] band. Therefore, infrared wavelengths longer than absorption wavelength (<1 [symbol] ) of the silicon wafer do not participate in the optical heating of the wafer, so the halogen lamp has low heating efficiency.

In order for the light with wavelength of 0.5 to 3 [symbol] emitted from the halogen lamp to be absorbed by the wafer and to participate in the light heating, the process temperature for the wafer must be at least 600° C. or higher. At a low temperature, such as a process temperature of wafer of 600 to 700° C., the light absorption rate is low, making rapid heating difficult, and the light absorption rate is sensitively changed depending on the dopant concentration and temperature of the wafer. When the wafer is directly heated without a susceptor, the halogen lamp is used in a way that the wafer is slowly preheated to around 700° C. and is then rapidly heated to a high temperature of 1,000°C or higher after a stabilization process. The halogen lamp makes rapid heating of the wafer difficult in the epitaxy process of 600 to 700° C. and makes precise temperature variation difficult. Therefore, the halogen lamp has an aspect that it is not suitable as a heating means in an epitaxy process of 600° C. or lower. In particular, in order to increase the Ge concentration (x) of the SiGeₓ thin film, this is especially true when the deposition temperature is 600° C. or lower.

The semiconductor device manufacturing apparatus 10 may be used to perform the manufacturing method for the semiconductor device of FIG. 1. For example, the semiconductor device manufacturing apparatus 10 may be used to form a multi-layered thin film of [Si/SiGeₓ]n on the flat substrate a through the epitaxy process. The semiconductor device manufacturing apparatus 10 may perform the epitaxy process in which the first thin film and the second thin film as alternately deposited. The semiconductor device manufacturing apparatus 10 may set the first deposition temperature and the second deposition temperature for depositing the second thin film differently. The semiconductor device manufacturing apparatus 10 may set the first deposition temperature relatively higher than the second deposition temperature in order to increase the first deposition rate for depositing the first thin film. The semiconductor device manufacturing apparatus 10 may set the first deposition temperature and the second deposition temperature so that the first deposition rate is 0.1 to 2 times higher than the second deposition rate.

The semiconductor device manufacturing apparatus 10 may directly support a periphery of a lower surface of the flat substrate without using a susceptor. Since the semiconductor device manufacturing apparatus 10 directly supports the flat substrate a, it is possible to rapidly rise or lower the temperature of the flat substrate a within a deposition temperature range of 400 to 1,000° C., of the epitaxy process. For example, the semiconductor device manufacturing apparatus 10 may shorten the time, spent on lowering the deposition temperature from the first deposition temperature to the second deposition temperature, to 1 to 10 seconds. In addition, the semiconductor device manufacturing apparatus 10 may shorten the time, spent on rising the deposition temperature from the second deposition temperature to the first deposition temperature, to 1 to 5 seconds. Furthermore, since the semiconductor device manufacturing apparatus 10 directly heats the flat substrate a, it is possible to reduce changes in the deposition temperature and deposition rate even in a bowing phenomenon of the flat substrate a occurred in the epitaxy process.

The bowing phenomenon (or bending phenomenon) is a phenomenon in which the silicon wafer is deformed into a concave or convex shape during the process of depositing a [Si/SiGe]n thin film on a silicon wafer. Since the SiGe thin film and the silicon wafer have differences in lattice distances of their crystal atomic arrangements, in the epitaxial growth in which the crystal lattices of Si and SiGe maintain alignment and grow, a lattice deformation occurs due to the lattice mismatch of Si and SiGe, and the wafer may be bent into a concave or convex shape. This bowing phenomenon is a phenomenon that inevitably occurs in heterogeneous epitaxial growth in which thin films of different materials grow into single crystals, and can be increased as the x composition in SiGeₓ increased and the number of layers of the multi-layered film (i.e., n in [Si/SiGeₓ]n) is increased.

When the epitaxy process is performed in a state in which the flat substrate (a) is supported on a susceptor, the flat substrate a may be partially bent into a concave or convex shape, whereby a contact degree between the flat substrate and a susceptor may be deteriorated. Uniformity of the deposition temperature may be deteriorated as heat transfer between the flat substrate a and the susceptor varies from a region to a region. Deterioration in the uniformity of the deposition temperature may cause an uneven deposition rate, thereby reducing uniformity of the deposition thickness and uniformity of the composition in the thin film. In addition, since the susceptor has a relatively large thermal mass, rapid rising and lowering of the deposition temperature may be difficult.

The semiconductor device manufacturing apparatus 10 may be used to manufacture a semiconductor device on the flat substrate a using a manufacturing process such as a crystallization process, an ion implantation process, or an activation process other than the epitaxy process.

The process chamber 100 may include an external housing 110, an internal housing 120, a laser beam transmitting plate 130, a substrate support 140, a separating partition 150, and an infrared transmitting plate 160.

The process chamber 100 may have a chamber upper space 100a, in which the flat substrate a is placed, formed in an upper portion of the external housing 110. The chamber upper space 100a is formed above the internal housing 120 within the external housing 110 and may provide a space in which the flat substrate a is placed and the epitaxy process is performed. In addition, in the process chamber 100, a chamber lower space 100b may be formed between the external housing 110 and the internal housing 120. The chamber lower space may provide a space in which a portion of the substrate rotating unit 400 is received.

In addition, the process chamber 100 may include a process gas supplying passage 100c configured to supply a process gas to the chamber upper space 100a, and a process gas discharging passage 100d configured to discharge the process gas to the outside. The process gas supplying passage 100c may be formed to extend from the outside of the external housing 110 to the chamber upper space 100a. The process gas supplying passage 100c may be formed in various ways depending on structures of the external housing 110, the infrared transmitting plate 160, and the separating partition 150. For example, the process gas supplying passage 100c may be formed to pass through the external housing 110, the infrared transmitting plate 160, and the separating partition 150. The process gas supplying passage 100c may be formed to supply the process gas in parallel to an upper surface of the flat substrate a. The process gas supplying passage 100c may be formed so that its end portion is parallel to the upper surface of the flat substrate at the same height. The process gas discharging passage 100d may be formed to extend from the chamber upper space 100a to the outside of the external housing 110. Like the process gas supplying passage 100c, the process gas discharging passage 100d may be formed in various ways depending on the structures of the external housing 110, the infrared transmitting plate 160, and the separating partition 150. For example, the process gas discharging passage 100d may be formed to pass through the separating partition 150 and the external housing 110.

The process gas may be introduced through the process gas supplying passage 100c and deposited as a thin film while flowing through a space between the upper surface of the flat substrate a and the infrared transmitting plate 160. Among the process gases, the unreacted process gas and a byproduct gas generated after deposition may be discharged to the outside of the process chamber 100 through the process gas discharging passage 100d. Meanwhile, hydrogen gas may be used as a carrier gas for transporting the process gas. Among the process gases, gases such as Si₂H₂Cl₂, SiH₄, Si₂H₆, Si₃H₈ may be used as the source gas for Si, and GeH₄ may be used as the source gas for Ge of SiGe. In addition, the process chamber 100 may maintain a reduced pressure condition of 0.1 to 500 Torr.

The flat substrate a may be supported by the substrate support 140 such its lower surface is exposed inside the process chamber 100. The process chamber 100 allows a laser beam irradiated from substrate heating unit 200 placed at the outside to pass through the laser beam transmitting plate 130 and be irradiated to the lower surface of the flat substrate a.

The external housing 110 may include an external upper wall 111, an external lower wall 113, an upper plate 115, and a lower plate 117. The external housing 110 may be formed in a hollow cylindrical shape overall. The external housing 110 may be formed in a roughly cylindrical shape, a square column shape, a pentagonal column shape, or a hexagonal column shape. The external housing 110 may be formed into a shape having a horizontal cross-sectional area larger than the area of the flat substrate a mounted therein.

The external housing 110 may be formed of a metal material that is durable against damage caused by fluctuation in pressure and temperature such that it can cope with positive and negative pressure conditions and rapid temperature change conditions that occur during manufacturing. In addition, the external housing 110 may be formed of a metal material that is corrosion resistant to the process gases used in the manufacturing process. The external housing 110 may be formed of a metal material such as stainless steel, Invar alloy, or Hastelloy.

The external upper wall 111 may be formed in a hollow cylindrical shape. The external upper wall 111 may be formed in a cylindrical shape, a square column shape, a pentagonal column shape, or a hexagonal column shape. The external upper wall 111 may have a partition mounting region 111a, in which the separating partition 150 is placed, protruded outward. Therefore, the external upper wall 111 may include a vertical wall and a horizontal wall extending inwardly from a bottom of the vertical wall by a predetermined width. The external upper wall 111 may provide a space in which a portion of the substrate rotating unit 400, the substrate supporter 140, and the flat substrate a are received.

The external upper wall 111 may have a side gas discharging hole 111b passing therethrough from an inner circumferential surface to an outer circumferential surface thereof. The side gas discharging hole 111b may provide a path through which a cooling gas, flowing through a side cooling gas passage formed in an inner side of the external upper wall 111, is discharged to the outside of the external upper wall 111.

The external lower wall 113 may be formed in a hollow cylindrical shape. The external upper wall 111 may be formed in a cylindrical shape, a square column shape, a pentagonal column shape, or a hexagonal column shape. The external lower wall 113 may be formed in the same or similar shape as or to the external upper wall 111. The external lower wall 113 may be formed to have a diameter or width less than that of the external upper wall 111. The external lower wall 113 may be coupled to a lower portion of the external upper wall 111. The external lower wall 113 may provide a space to receive the internal housing 120 and a portion of the substrate rotating unit 400 therein.

The upper plate 115 may be formed in a plate shape corresponding to a top plane shape of the external upper wall 111. The upper plate 115 may be coupled to an upper portion of the external upper wall 111 to shield the upper portion of the external upper wall 111. The upper plate 115 may be formed of a metal material such as stainless steel, Invar alloy, or Hastelloy.

The upper plate 115 may include an upper opening 115a formed in an inward side thereof and extending from an upper surface to a lower surface thereof. The upper opening 115a may be formed to have a diameter or width necessary for exposing the entire infrared transmitting plate 160. The upper opening 115a may provide a space in which an upper portion of the infrared transmitting plate 160 is exposed and the cooling gas injected from the cooling gas injection unit 300 flows to an upper surface of the infrared transmitting plate 160. Therefore, the upper opening 115a may form an upper cooling gas passage 100e above the infrared transmitting plate 160. The cooling gas may be nitrogen (N₂), argon (Ar), or dry air. The cooling gas may cool the infrared transmitting plate 160.

The upper plate 115 may further include a ring-shaped upper support ring 116 extending downward from a lower surface of the inward side thereof. The upper support ring 116 may be formed to have predetermined height and width. The upper support ring 116 may be coupled to the infrared transmitting plate 160 such that a lower surface thereof comes into contact with the outer upper surface of the infrared transmitting plate 160. The upper support ring 116 may increase a height of the upper cooling gas passage 100e to increase a time for which the cooling gas stays in the upper cooling gas passage. Therefore, the infrared transmitting plate 160 may be effectively cooled while reducing the amount of use of the cooling gas.

The upper plate 115 may include an upper gas discharging hole 115b extending from the upper cooling gas passage 100e to the outside of the infrared transmitting plate 160 or the separating partition 150. The upper gas discharging hole 115b may be extended to a side cooling gas passage 100f formed between an outer side of the separating partition 150 and the external housing 110. The upper gas discharging hole 115b may be extended from an inner circumferential surface to an outer circumferential surface of the upper support ring 116 to have a linear shape. In addition, in the case where the upper support ring 116 is not formed on the upper plate 115, the upper gas discharging hole 115b may be formed in a shape that is bent from the upper opening 115a to a lower surface of the upper plate 115. The upper gas discharging hole 115b may provide a passage through which the cooling gas in the upper cooling gas passage 100e is discharged to the outside of the separating partition 150. In addition, the upper gas discharging hole 115b may provide a passage through which the cooling gas is discharged to the side cooling gas passage 100f.

The lower plate 117 may be formed in a plate shape corresponding to a planar shape of a lower end of the external lower wall 113. The lower plate 117 may include a lower opening 117a formed in an inward side thereof and extending from an upper surface to a lower surface thereof. The lower plate 117 may be formed as a circular ring or a square ring having a predetermined width. The lower plate 117 is coupled to the lower end of the external lower wall 113 and may shield an outer side of the external lower wall 113. The lower plate 117 may seal a space between the external lower wall 113 and a lower side of the internal housing 120. That is, the lower plate 117 may seal a lower portion of the chamber lower space 100b. The lower plate 117 may be formed of a metal material such as stainless steel, Invar alloy, or Hastelloy.

The internal housing 120 is formed in a hollow cylindrical shape, and may be formed in a cylindrical shape, a square column shape, a pentagonal column shape, or a hexagonal column shape. The internal housing 120 may be formed to have an outer diameter or outer width smaller than an inner diameter or an inner width of the external lower wall 113. In addition, the internal housing 120 may be formed having a height lower than the external lower wall 113. Also, the internal housing 120 may be formed with a height such that the flat substrate a is placed on an upper end thereof within the process chamber 100. Furthermore, the internal housing 120 may be formed to have a diameter or width larger than a diameter or width of the flat substrate a. In addition, the internal housing 120 may be formed to have a horizontal area larger than that of the flat substrate a.

In addition, the internal housing 120 may be coupled to the lower plate such that a lower side thereof is placed at approximately the same height as a lower side of the external housing 110. A lower end of the internal housing 120 may be coupled to an inner side of the lower plate 117. A space between an outer side of the internal housing 120 and the inner side of the external housing 110 may be sealed by the lower plate 117. The internal housing 120 may be formed of a metal material such as stainless steel, Invar alloy, or Hastelloy.

The laser beam transmitting plate 130 may be coupled to the upper end of the internal housing 120 to seal the upper end of the internal housing 120. The laser beam transmitting plate 130 may be placed below the flat substrate a. The laser beam transmitting plate 130 may be formed of a transparent plate through which a laser beam is transmitted, such as quartz or glass. The laser beam transmitting plate 130 may provide a passage through which a laser beam irradiated from the substrate heating unit 200 is irradiated to the lower surface of the flat substrate a. The laser beam transmitting plate 130 may be formed to have an area larger than that of the flat substrate a. For example, the laser beam transmitting plate 130 may be formed to have a diameter or width larger than a diameter or width of the flat substrate a.

The substrate support 140 may include an upper support 141 and a side support 143. The substrate support 140 may be positioned above internal housing 120 to support a periphery of the lower surface of the flat substrate a such that the lower side of the flat substrate a is exposed. That is, the substrate support 140 may directly support a periphery of the lower surface of the flat substrate a without using a susceptor. Therefore, the flat substrate a may be rapidly heated and cooled between 400 and 1,000° C. which is the deposition temperature range of the epitaxy process. That is, the flat substrate a may be cooled from the first deposition temperature to the second deposition temperature in a short time, and conversely, may be heated in a short time. In addition, the substrate support 140 may be extended to the chamber lower space 100b to be coupled to the substrate rotating unit (400). The substrate support 140 may rotate the flat substrate a using an operation of the substrate rotating unit 400. A separate hydrogen gas may be supplied to an internal space of the substrate support 140. The hydrogen gas may prevent the process gas from flowing into the internal space of the substrate support 140. Therefore, the hydrogen gas may prevent Si thin film or a SiGe thin film from being deposited on the lower surface of the flat substrate a by the process gas. Although not specifically illustrated, the hydrogen gas may flow into an interior of the substrate support 140 through a separate inlet port.

The upper support 141 may be provided with a substrate exposing opening 141a formed in an inward side thereof to be formed as a ring shape having a predetermined width. The upper support 141 may support a periphery of the lower surface of the flat substrate a while exposing the lower surface of the flat substrate a. The upper support 141 may be formed to have a diameter or width larger than a diameter or width of the flat substrate a.

The substrate exposing opening 141a may be formed by extending from an upper surface to a lower surface at a central portion of the upper support 141. The substrate exposing opening 141a may be formed with a predetermined area so as to be able to fully expose the region, on which the semiconductor device is formed, of the lower surface of the flat substrate a.

The side support 143 is formed in a roughly cylindrical shape with opened upper and lower ends, and may be formed in a shape corresponding to the shape of the internal housing 120. For example, when the internal housing 120 is formed in a cylindrical shape, the side support 143 may be formed in a cylindrical shape corresponding thereto. The side support 143 may be placed across the chamber upper space 100a and the chamber lower space 100b. On the side support 143, an upper portion is coupled to an outer side of the upper support 141 and a lower portion may be extended to the chamber lower space 100b to be coupled to the substrate rotating unit 400. Therefore, the side support 143 may rotate the upper support 141 and the flat substrate a while being rotated by the substrate rotating unit 400.

The separating partition 150 is formed in a ring shape having a predetermined height, and may be formed to have an outer diameter smaller than an inner diameter of the external upper wall 111. The separating partition 150 may be formed to have an inner diameter corresponding to an inner diameter of the external lower wall 113. The separating partition 150 may be formed to have a height smaller than a height of the external upper wall 111. The separating partition 150 may be placed at an inward side of the external upper wall 111. That is, the separating partition 150 may be placed on the partition mounting region 111a provided at an inward side of the external upper wall 111. The side cooling gas passage 100f, through which a cooling gas flows, may be formed between the separating partition 150 and the external upper wall 111. The separating partition 150 may be formed of a transparent material such as quartz or glass. The side cooling gas passage 100f may provide a passage through which a cooling gas supplied from the outside flows. The side cooling gas passage 100f may be formed in a ring shape to surround an outer circumference surface of the separating partition 150. The side cooling gas passage 100f may allow a cooling gas flowing through the upper cooling gas passage 100e to flow thereinto. In addition, the side cooling gas passage 100f may allow a cooling gas to flow thereinto separately. The side cooling gas passage 100f may allow a cooling gas to flow while coming into contact with an outer circumference surface of the separating partition 150, so that the separating partition 150 may be maintained at a required temperature. The process chamber 100 may control a flow rate of cooling gas flowing through the side cooling gas passage 100f in real time to allow a temperature of the separating partition to be maintained constant during the epitaxy process.

The infrared transmitting plate 160 may be formed in a plate shape corresponding to a planar shape of the separating partition 150. The infrared transmitting plate 160 may be formed of a transparent material such as quartz or glass. The infrared transmitting plate 160 may be coupled to an upper portion of the separating partition 150 to seal an upper portion of the separating partition 150. The infrared transmitting plate 160 may be coupled to a lower side of the upper opening 115a of the upper plate 115 to seal the upper opening 115a. That is, the infrared transmitting plate 160 may be coupled between the separating partition 150 and the upper plate 115. The infrared transmitting plate 160 may be placed above the flat substrate a such that a lower surface thereof faces the upper surface of the flat substrate a on the upper portion of the flat substrate a.

The infrared transmitting plate may transmit radiation energy, which is generated from the flat substrate a during the epitaxy process, to the outside. In particular, the infrared transmitting plate 160 may transmit radiation energy with a wavelength including infrared to the outside.

In addition, the infrared transmitting plate 160 is maintained at a temperature of 400° C. or less, and preferably, may be maintained at a temperature of 300 to 400° C. Since the infrared transmitting plate 160 is maintained at a temperature of 300 to 400° C., deposition by the source gas is prevented, and an increase in emissivity due to deposition can be thus prevented. In addition, since the emissivity of the infrared transmitting plate 160 is not increased with the number of times of the epitaxy process, it is possible to reduce the difference in deposition temperature between the flat substrates a on which the process is performed.

The substrate heating unit 200 may include a device array plate 210 and VCSEL modules 220. In addition, the substrate heating unit may further include a pyrometer 230. The substrate heating unit 200 may be placed below the laser beam transmitting plate 130 inside the internal housing 120 of the process chamber 100. The substrate heating unit 200 may irradiate a laser beam to the lower surface of the flat substrate a through the laser beam transmitting plate 130. The substrate heating unit 200 may be configured such that the laser beam is irradiated over a wide outer range of 30 to 60 [symbol] outward from an edge of the flat substrate a. In addition, a distance between the VCSEL module 220 and the flat substrate a may be 100 to 300 [symbol] .

In the substrate heating unit 200, the plurality of VCSEL modules 220 may be arranged on an upper surface of the device array plate 210 in a lattice form. Referring to FIG. 5, the VCSEL modules 220 may be arranged on the upper surface of the device array plate 210 in a x-direction and a y-direction to be arranged in a lattice shape.

The device array plate 210 may be formed in a plate shape having predetermined area and thickness. The device array plate 210 may be preferably formed to correspond to a shape and area of the flat substrate a. The device array plate 210 may be formed to have an area larger than the area of the flat substrate a. The device array plate 210 may be formed to have an area necessary for arranging the VCSEL modules 220 such that the laser beam is irradiated over a wide outer range of 30 to 60 [symbol] outward from an edge of the flat substrate a.

The device array plate 210 may be formed of a thermally conductive ceramic material or metallic material. The device array plate 210 may function to radiate heat generated from the VCSEL modules 220.

The VCSEL module 220 may be formed to include a plurality of VCSEL devices. The VCSEL module 220 may include a device substrate 221, VCSEL devices 223, an electrode terminal 225, and a cooling block 227. The plurality of VCSEL modules 220 may be arranged and positioned on the device array plate in a grid direction. The VCSEL modules 220 may arranged in a region, which is required to irradiate the laser beam to a region of the flat substrate a on which a thin film will be formed, of the surface of the device array plate 210. the VCSEL modules 220 may be arranged such that the laser beam is irradiated over a wide outer range of 30 to 60 [symbol] outward from an edge of the flat substrate a. The device substrate 221 may be coupled to the cooling block 227 by a separate adhesive layer 226.

The VCSEL module 220 uses radiation characteristics of the laser beam emitted from a VCSEL device 223, and may uniformly heat the flat substrate a using the characteristics that the laser beams emitted from the adjacent VCSEL devices 223 are overlapped with each other.

The VCSEL module 220 is formed by arranging the plurality of VCSEL devices 223 in the x-axial direction and the y-axial direction. The VCSEL module 220 may be formed such that the same power is applied to the entire VCSEL devices 223. In addition, the VCSEL module 220 may be formed such that different powers are applied to each of the VCSEL devices 223.

The VCSEL module 220 may irradiate the laser beam from below the flat substrate a to heat the flat substrate a. In the case where the laser beam is irradiated to an upper portion of the flat substrate a, there is a problem that it is difficult to realize a uniform surface temperature because the reflectivity of the laser beam varies due to the pattern of the device formed on the surface of the flat substrate a and a material other than silicon (i.e., metal, SiO₂, Si₃N₄, etc.). In addition, if Si or SiGe is deposited on the infrared transmitting plate 160 placed above the flat substrate a, beam absorption may be occurred on the infrared transmitting plate 160, and the beam irradiation intensity may be altered.

The device substrate 221 may be formed as a general substrate used for mounting electronic elements. The device substrate 221 may be divided into a device region 221a on which a plurality of micro-emitters are mounted, and a terminal region 221b on which a terminal is mounted. On the device region 221a, the plurality of micro-emitters are arranged and mounted in a grid shape. The terminal region 221b is placed adjacent to the device region 221a and a plurality of terminals may be mounted thereon.

The plurality of VCSEL devices 223 are formed and arranged on an upper surface of the device substrate 221 in the x-axial direction and the y-axial direction. The VCSEL device 223 may be irradiate the laser beam with a single wavelength of 940 [symbol] . Since the VCSEL device 223 oscillates a high-power laser beam, this VCSEL device may increase the temperature rising rate of the flat substrate a and also has a relatively long lifespan, as compared with a conventional halogen lamp.

The VCSEL device 223 is formed by arranging a plurality of micro-emitters in the x-axial direction and the y-axial direction. Although not specifically illustrated, the VCSEL device 223 may be provided with a light-emitting frame (not shown) for fixing the micro-emitter and a power line (not shown) for supplying current to the micro-emitter. The VCSEL device 223 may be configured to apply the same current to all of the entire micro-emitters. In addition, the VCSEL device 223 may be configured to apply different power to each micro-emitter.

On the upper surface of the device substrate 221, the plurality of micro-emitters may be arranged on device region 221a in the x-direction and the y-direction to be arranged in a lattice shape. An appropriate number of the micro-emitters may be placed at appropriate intervals according to the area of the device region 221a and the amount of energy of the laser beam irradiated to the flat substrate a. In addition, the micro-emitters may be placed at intervals, and this interval is set such that uniform energy may be irradiated when a laser beam emitted from one micro-emitter overlaps a laser beam of the adjacent micro-emitter.

The plurality of the electrode terminals 225 may be formed in the terminal region 221b of the device substrate 221. The electrode terminals 225 includes a +terminal and a −terminal, and may be electrically connected to the VCSEL devices 223. Although not specifically illustrated, the electrode terminal 225 may be electrically connected to the VCSEL device 223 in a various ways. The electrode terminal 225 may supply power required for driving the VCSEL device 223.

The cooling block 227 may be formed to have a planar shape corresponding to a planar shape of the device substrate 221, and a predetermined height. The cooling block 227 may be formed of a thermally conductive ceramic material or metallic material. The cooling block 227 may be coupled to a lower surface of the device substrate 221 by a separate adhesive layer. The cooling block 227 may radiate heat generated from the VCSEL devices 223 mounted on a surface of the device substrate 221 downward. Accordingly, the cooling block 227 may cool the device substrate 221 and the VCSEL devices 222. Reference number 226, which is not mentioned, may be an adhesive layer that bonds the device substrate 221 and the cooling block 227.

In addition, a cooling passage (not shown) through which cooling water flows may be formed in the cooling block 227. The cooling passage may have an inlet port and an outlet port formed on a lower surface of the cooling block, and may be formed in the cooling block 227 as various types of passages.

The pyrometer 230 may measure a temperature of the flat substrate in a non-contact manner. The pyrometer 230 may measure the temperature of the flat substrate more accurately by using 1 [symbol] band. The pyrometer 230 may be placed below a through hole (not shown) formed in the VCSEL module 220. The pyrometer 230 may measure the temperature from the lower surface of the flat substrate through the through hole. In addition, the pyrometer 230 may be placed above the flat substrate a. The pyrometer 230 may measure the temperature on the flat substrate a. Therefore, the pyrometer detects the temperature of the flat substrate on or below the flat substrate, and may allow the VCEL sub-module to heat the flat substrate to a predetermined deposition temperature.

Since Si thin film or a SiGeₓ thin film is deposited on the flat substrate a, the emissivity of the surface of the flat substrate a is changed. Therefore, the pyrometer 230 may preferably measure a temperature of the lower surface of the flat substrate a. Meanwhile, the pyrometer 230 may cause interference between the laser beam of the VCSEL module 220 and a detection light source of the pyrometer. Since the laser beam irradiated from the VCSEL module 220 is a single-wavelength laser beam, there is an advantage in that this can be distinguished from the wavelength band used by the pyrometer 230 to detect the temperature. Therefore, since the laser beam of the VCSEL module does not interfere with the temperature detection of the pyrometer, the pyrometer may accurately read the temperature of the flat substrate even at a low temperature of 800° C. or less.

The plurality of pyrometers 230 may be distributed and positioned at a lower portion of the VCSEL module 220. The pyrometers 230 may be positioned spaced apart from each other in a radial direction from a center of the VCSEL module 220 to an outer edge. The pyrometers are positioned to correspond to the VCSEL sub-modules, respectively, and may measure the temperature of the wafer corresponding to each region heated by the VCSEL sub-module. Applied outputs are individually fed back to the VCSEL sub-modules corresponding to each region such that the same temperature is input from the pyrometers 230 during a rotation process of the flat substrate a, thus the temperature of the wafer may be uniformly controlled.

The cooling gas injection unit 300 may include an injection housing 310 and a gas injection plate 320. The cooling gas injection unit 300 may inject a cooling gas on the upper surface of the infrared transmitting plate 160 to cool the infrared transmitting plate 160. The cooling gas may be nitrogen (N₂) gas, argon (Ar) gas, or compressed cooling air.

The injection housing 310 may include a cooling gas inflow hole 311. The injection housing 310 may be formed in a hollow cylindrical shape with an opened lower end. The injection housing 310 may be formed to have a planar shape corresponding to the upper plate 115 of the external housing 110. The injection housing 310 may have a cooling gas inflow space, into which a cooling gas flows, formed therein.

The cooling gas inflow hole 311 may have a hole shape formed an upper plate or a side plate of the injection housing 310 and extending from the outside to the inside of the injection housing, i.e., the cooling gas inflow space. One or the plurality of cooling gas inflow holes 311 may be formed depending on a planar area of the injection housing 310. The cooling gas inflow hole 311 may provide a path allowing a cooling gas to flow into the cooling gas inflow space.

The gas injection plate 320 may include a gas injection hole 321. The gas injection plate 320 is formed in a plate shape and may be formed to have an area corresponding to a planar area of the injection housing 310. The gas injection plate 320 may be coupled to a lower portion of the injection housing 310 to enable the lower portion of the injection housing 310 to be shielded.

The gas injection hole 321 is formed in the gas injection plate 320 and extended from an upper surface to a lower surface of the gas injection plate 320. The gas injection hole 321 may connect the cooling gas inflow space and the upper opening 115a of the upper plate 115. The gas injection hole 321 may inject a cooling gas, which flows into the cooling gas inflow space from the outside, to the upper opening 115a and the infrared transmitting plate 160.

The plurality of gas injection holes 321 may be spaced apart from each other across and formed in the entire gas injection plate 320. The gas injection holes 321 may inject a cooling gas more evenly onto the infrared transmitting plate 160. Therefore, the gas injection plate 320 may cool the infrared transmitting plate 160 placed therebelow more evenly.

The substrate rotating unit 400 may include an inner rotating means 410 and an outer rotating means 420. The substrate rotating unit 400 may rotate the substrate support 140 in a horizontal direction in a non-contact manner. More specifically, the inner rotating means 410 may be coupled to a lower portion of the substrate support 140 in the chamber lower space 100b of the process chamber 100. In addition, the outer rotating means 420 may be positioned to face the inner rotating means 410 at the outside of the process chamber 100. The outer rotating means 420 may rotate the inner rotating means 410 in a non-contact manner using a magnetic force.

The inner rotating means 410 may be formed to have the same structure as a rotor of a motor. For example, the inner rotating means 410 may be formed as a magnet structure that is formed in a ring shape as a whole and has N poles and S poles alternately arranged in a circumferential direction. The inner rotating means 410 may be coupled to the side support 143 of the substrate support 140. At this time, the inner rotating means 410 may be positioned to be spaced upward apart from an upper portion of the lower plate 117. Meanwhile, although not specifically illustrated, the inner rotating means 410 may be supported by a separate support means such that vibration is prevented during rotation or it can be rotated smoothly. For example, a lower portion of the inner rotating means 410 may be supported by a support bearing or roller.

The outer rotating means 420 may be formed to have the same structure as a stator of a motor. For example, the outer rotating means 420 may include an iron core formed in a shape of ring and a conducting wire wound around the iron core. The outer rotating means 420 may rotate the inner rotating means 410 with a magnetic force generated by power supplied to the conducting wire. The outer rotating means 420 may be placed outside the external housing 110 to allow both rotating means to fac each other with respect to the external housing 110. In other words, the outer rotating means 420 may be placed outside the external housing with the respect to the external housing 110 at the same height as the inner rotating means 410.

The following describes in more detail the substrate heating unit 200 of the semiconductor device manufacturing apparatus 10 for the manufacturing method for the semiconductor device according to one embodiment of the present invention.

The substrate heating unit 200 may be comprised of a plurality of VCSEL modules 220.

Each of the VCSEL modules 220 may be comprised of a plurality of VCSEL devices 223. In addition, on each VCSEL module 220, at least two VCSEL sub-modules are formed and arranged. Each VCSEL sub-module may have the device region 221a in which the VCSEL devices 223 are arranged at regular intervals, and the terminal region 221b connecting the VCSEL devices 223 in series or in parallel and connecting them to an external power source. In addition, each VCSEL module 220 may have at least two element regions 221a and at least two terminal regions 221b. The VCSEL module 220 is composed of at least two VCSEL sub-modules and the VCSEL modules may be arranged in a plane so as to irradiate the laser beam to the entire region of the flat substrate a.

The VCSEL device 223 has a rectangular shape with a width of approximately 1 to 2 [symbol] , and may have an emitter region in which a plurality of micro-emitters are formed, and an electrode region in which an electrode electrically connecting the micro-emitters is formed. The VCSEL device 223 does not have a source of laser beam of the micro-emitter in the electrode region. Therefore, a distribution and intensity of the laser beam in the electrode region are determined by the overlap caused by a divergence of the laser beam of the adjacent micro-emitter. The micro-emitter has a divergence angle of 10 to 30°. Therefore, in order for the intensity of the laser beam irradiated from the VCSEL device 223 to be uniform, a shape and intensity of the overlapped laser beam in the electrode region must be the same as the shape and intensity of the laser beam emitted from the emitter region of the micro-emitter. The shape and intensity of the laser beam is changed depending on the overlap distance. Therefore, the uniformity of the beam intensity of the VCSEL module 220 is affected by the size and arrangement shape of the electrode region existing in the VCSEL device unit (short-range array), the VCSEL sub-module unit (medium-range array), and the entire module unit (long-range array).

Since the overlap between the laser beams emitted from the micro-emitters is altered depending on a separation distance between the flat substrate a and the micro-emitter, a specific separation distance which leads to the best uniformity. This separation distance is optimized at a distance where the overlap of the laser beams over short, medium, and long ranges is optimized, and the optimized separation distance is preferably 100 to 300 [symbol] for the implementation of the epitaxy process apparatus. That is, the separation distance between the VCSEL device 223 or the VCSEL module 220 and the flat substrate a may be 100 to 300 [symbol] .

In a short-range array in which the micro-emitters placed within the VCSEL device 223 are arranged and the electrodes are arranged, a pitch between the micro-emitters, i.e., a maximum separation distance may be 0.1 [symbol] . Assuming that the area of the electrode is 1/10 of the device size (1 [symbol] ×1 [symbol] ), the electrode region may be formed to be smaller than 0.1 [symbol] . In addition, the pitch of the electrodes may be 0.1 [symbol] . Since there is no micro-emitter in the electrode space within the VCSEL, the non-uniformity of the beam energy emitted is 0.01%. Therefore, the short-range arrangement inside the VCSEL device 223 does not cause a problem in achieving the desired uniformity of the deposition temperature of 0.2%.

In the arrangement (medium-range array) in which the VCSEL devices 223 are arranged within the VCSEL sub-module, if a separation between the VCSEL device 223 and the VCSEL device 223 is 1 [symbol] or less, the non-uniformity of the generated beam energy may be 0.1% or less. If a separation between the VCSEL device 223 and the VCSEL device 223 exceeds 1.5 [symbol] , the non-uniformity of the beam energy becomes worse to 0.2% or more. Therefore, in order to achieve a uniformity of beam energy of 0.2% or less in the VCSEL devices, the separation distance between the VCSEL device and the VCSEL device must be at least 1 [symbol] or less.

The VCSEL sub-module requires the terminal region 221b on which an input terminal and an output terminal are formed to connect to an external power source, and a required area for this must be at least 5 [symbol] ×5 [symbol] or more. If a size of the terminal region 221b is at least 5 [symbol] or more, the non-uniformity of the beam energy generated may be several percent or more because the laser beam is not generated from the terminal. In addition, the VCSEL module 220 in which the VCSEL sub-modules are arranged has an empty space, including the terminal region 221b of the VCSEL sub-module, of at least 5 [symbol] ×5 [symbol] , and if the size of the empty space becomes larger, the non-uniformity of the beam energy may be further deteriorated.

The VCSEL module 220 may be formed to have a structure in which two VCSEL sub-modules are combined to each other, as shown in FIG. 5. The terminal regions 221b of the VCSEL sub-modules are positioned diagonally from each other in the VCSEL module 220 and may be protruded in opposite directions. The terminal region 221b may be formed in an approximately rectangular shape.

In the VCSEL module 220, empty regions including the terminal regions 221b are arranged in a linear manner along one direction. When the empty regions including the terminal regions 221b are arranged in a linear manner, the overlap of the laser beams generated in the empty regions occurs in a vertical direction of the terminal regions 221b, and since the overlapping distance in this direction is constant throughout the entire VCSEL module 220, it is possible to create laser beams that overlap in the same shape.

In the VCSEL module 220, the VCSEL sub-modules may be arranged such that the terminal regions 221b are aligned in a straight line. In the VCSEL sub-module, it is preferable that a length of one side of the rectangular or square device region 221a is greater than 10 [symbol] and less than 40 [symbol] . If the length of the device region 221 a is too short, the number of VCSEL sub-modules corresponding to the flat substrate region is increased excessively, and it is difficult to form the terminal region 221b. In addition, if the length of one side of the device region 221a is too long, the number of VCSEL sub-modules is decreased, but the range of the flat substrate region, for which each VCSEL sub-module is responsible, is expanded, making it difficult to control the region for adjusting a local temperature deviation.

In the VCSEL module 220, the terminal region 221b protruding from the device region 221a may be determined by considering a size of the terminal and a wiring, and a length of portion protruding from the device region 221 a may be preferably 10 [symbol] or less. For example, a length of this protruded portion may be 7 [symbol] . The VCSEL module 220 is formed by arranging the plurality of VCSEL sub-modules, and the terminal regions 221b may be arranged to form a straight line in one direction. The VCSEL module 220 may be arranged such that a separation distance between the VCSEL sub-modules is less than 10 [symbol] .

The following describes the evaluation results of the semiconductor device manufacturing apparatus of the present invention.

FIG. 6 is a graph showing uniformity of the laser beam according to a separation distance between the VCSEL module and the wafer. An overlap of the laser beams irradiated from the VCSEL module occurs in the terminal region existing between adjacent VCSEL modules-the terminal regions of these VCSEL modules face each other-, and the same overlap effect may be obtained because the overlap distance is the same. The separation distances at which the overlap unevenness of the laser beam is minimum are 120 [symbol] and 250 [symbol] . At the separation distance of 120 [symbol] , the overlap occurs between the closest VCSEL devices, and, at the separation distance of 250 [symbol] , the overlap is the overlap in which the closest VCSEL device and the second-distant VCSEL device from the terminal participate simultaneously. The overlap uniformity at the separation distance of 120 [symbol] is 0.6%, and the overlap uniformity at the separation distance of 250 [symbol] is 0.25%. The VCSEL module may obtain the extremely good uniformity of 0.25% when the separation distance is 250 [symbol] , but may not reach the required uniformity of 0.2%.

In order for the VCSEL module to implement the uniformity of deposition temperature of 0.2% or less, the wafer may be rotated. In the VCSEL module, overlapping non-uniform regions may be distributed linearly in one-dimension. Therefore, the linear non-uniform region may be efficiently homogenized by a rotation of the wafer. The degree of homogenization is changed depending on a rotation speed of the wafer, and the uniformity of 0.1% may be obtained at a rotation speed of 20 to 50 rpm which is suitable for the epitaxy process.

Meanwhile, the terminal region of the VCSEL module is a region where the laser beams emitted from adjacent VCSEL devices overlap each other. Therefore, a width of the terminal region may affect the uniformity. Since the laser beam emitted from the micro-emitter of the VCSEL device has a Gaussian (TEM00 mode) or M-shaped (TEM01 mode) beam profile, the intensity of the overlapped beams does not exactly match the intensity of the beam within the VCSEL device. Therefore, the uniformity of the VCSEL module may be improved when the overlap distance is small. When a width of the terminal region is increased from 0.7 [symbol] to 1.1 [symbol] , the uniformity becomes worse to 0.76%. Therefore, in order to obtain the desired uniformity of 0.2% or less, a width of the terminal region of the VCSEL module must be 10 [symbol] or less. Therefore, the VCSEL module may realize the uniformity of 0.2% required in the epitaxy process by arranging the VCSEL sub-modules as described above and rotating the wafer.

In addition, a zone control in a radial direction from a center to a periphery of the VCSEL module may divide the VCSEL sub-modules to configure the divided VCSEL sub-modules as the same zone and mount the plurality of pyrometers which measures the temperature on the wafer corresponding to each zone. Applied outputs are individually fed back to the VCSEL sub-modules corresponding to each region such that the same temperature is input from the pyrometers during a rotation process of the wafer, thus the temperature of the wafer may be uniformly controlled.

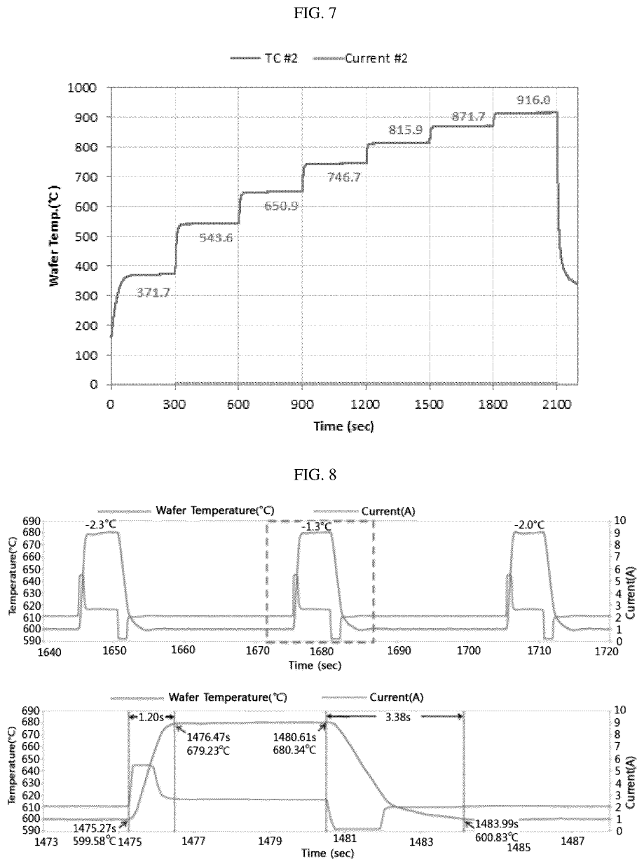

FIG. 7 is a graph showing the temperature of the wafer measured when heating the wafer while increasing the power applied to the VCSEL module. The temperature-rising rate is approximately 150° C. /sec. It can be seen that the wafer is rapidly heated even at the temperature of 600° C. or lower. Therefore, it can be confirmed that in the VCSEL module, it is possible to achieve rapid temperature variation required for the epitaxy process of the present invention even at a low temperature of 600° C. or lower.

FIG. 8 is a graph showing the temperature-variable characteristics of the wafer when the wafer is heated with the VCSEL module. The wafer was repeatedly heated and cooled between 600° C. and 680° C.

The time required for heating the wafer from 600° C. to 680° C. is 1.2 seconds, and no overheating occurs. In addition, the time required for cooling the wafer from 680° C. to 600° C. is approximately 3 seconds, and no underheating occurs.

As a result of evaluating a general epitaxy equipment under the same conditions, it is estimated that it takes approximately 90 to 150 seconds for heating and cooling the wafer. Therefore, the semiconductor device manufacturing apparatus according to one embodiment of the present invention may heat and cool the wafer within 1 to 3 seconds, thereby increasing the rate of manufacturing a multi-layered film of [Si/SiGeₓ]n by 2 to 10 times.

In order to help those skilled in the art to understand, the most preferred embodiments are selected from the various implementable embodiments of the present disclosure, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

### INDUSTRIAL APPLICABILITY

The present invention may be applied to the field of manufacturing the semiconductor device using an epitaxy process and the field of manufacturing the apparatus employing for manufacturing the semiconductor device.

1. A method of heating a flat substrate with a VCSEL devise and forming a multilayer thin film in which a first thin film and a second thin film are alternately deposited on a top of the flat substrate through an epitaxy process, the manufacturing method for the semiconductor device comprising:
a first thin film deposition step of supplying a first source gas at a first deposition temperature to deposit the first thin film to the top surface of the flat substrate;
a deposition temperature-lowering step of lowering a temperature of the flat substrate from the first deposition temperature to a second deposition temperature;
a second thin film deposition step of supplying a second source gas at the second deposition temperature to deposit the second thin film to a top surface of the first thin film; and
a deposition temperature-rising step of rising the temperature of the flat substrate from the second deposition temperature to the first deposition temperature.

2. The manufacturing method for the semiconductor device of claim 1, wherein the first thin film is Si thin film, and the second thin film is SiGeₓ(0.1<x<0.4) thin film.

3. The manufacturing method for the semiconductor device of claim 2, wherein the first deposition temperature is 600 to 800° C., the second deposition temperature is 500 to 750° C., the time for lowering the deposition temperature in the deposition temperature-lowering step is 1 to 10 seconds, and the time for rising the deposition temperature in the deposition temperature-rising step is 1 to 5 seconds.

4. The manufacturing method for the semiconductor device of claim 1, wherein the first deposition temperature and the second deposition temperature are set such that the first deposition rate of the first thin film is 0.1 to 2 times the second deposition rate of the second thin film.

5. The manufacturing method for the semiconductor device of claim 1, wherein, in the first thin film deposition step and the second thin film deposition step, the first deposition temperature and the second deposition temperature are controlled such that the uniformity is 0.2% or less.

6. The manufacturing method for the semiconductor device of claim 1, wherein a periphery of the flat substrate is supported such that a lower surface thereof is exposed, a laser beam irradiated from the VCSEL device is directly irradiated to the lower surface of the flat substrate, and the flat substrate is rotated when the laser beam is irradiated.

7. The manufacturing method for the semiconductor device of claim 1,
wherein a substrate heating unit including the VCSEL device irradiating the laser beam for heating the flat substrate is used,
wherein the substrate heating unit has a VCSEL module formed by combining at least two VCSEL sub-modules having a device region on which the at least two VCSEL devices are arranged and a terminal region on which terminals for supplying power to the VCSEL devices are arranged,
wherein the VCSEL module is arranged on an area larger than an area of the flat substrate,
wherein a separation distance between the VCSEL module and the flat substrate is 100 to 300 [symbol] .

8. The manufacturing method for the semiconductor device of claim 7, wherein the VCSEL sub-modules of the VCSEL module are arranged such that the terminal regions of the VCSEL sub-modules are linearly connected to each other in one direction.

9. The manufacturing method for the semiconductor device of claim 7,
wherein the VCSEL module irradiates a laser beam such that the temperature of the flat substrate has a temperature uniformity of 0.2% or less,
wherein the VCSEL device has a maximum separation distance of the micro-emitter array of 0.1 [symbol] and a size of the electrode region smaller than 0.1 [symbol] ,
wherein the VCSEL sub-module has a separation distance of the VCSEL devices smaller than 1 [symbol] ,
wherein the VCSEL module is arranged such that the separation distance of the VCSEL sub-modules is smaller than 10 [symbol] .

10. The manufacturing method for the semiconductor device of claim 7,
wherein the VCSEL sub-modules are independently supplied with power,
wherein light emitting intensities of the VCSEL sub-modules are individually controlled such that the flat substrate is heated to a predetermined deposition temperature using a pyrometer detecting the temperature of the flat substrate below the flat substrate.

11. The manufacturing method for the semiconductor device of claim 7, wherein the flat substrate is rotated by a magnetic levitation method, and the flat substrate is rotated without interference from the VCSEL module during rotation.

12. A semiconductor device manufacturing apparatus in which the manufacturing method for the semiconductor device of claim 1 is performed, the semiconductor device manufacturing apparatus, characterized in that:
wherein a substrate heating unit including the VCSEL device irradiating the laser beam for heating a flat substrate is used,
wherein the substrate heating unit has a VCSEL module formed by combining at least two VCSEL sub-modules having a device region on which the at least two VCSEL devices are arranged and a terminal region on which terminals for supplying power to the VCSEL devices are arranged,
wherein the VCSEL module is arranged on an area larger than an area of the flat substrate,
wherein a separation distance between the VCSEL module and the flat substrate is 100 to 300 [symbol] .

13. The semiconductor device manufacturing apparatus of claim 12, wherein the VCSEL sub-modules of the VCSEL module are arranged such that the terminal regions of the VCSEL sub-modules are linearly connected to each other in one direction.

14. The semiconductor device manufacturing apparatus of claim 12,
wherein the VCSEL module irradiates a laser beam such that the temperature of the flat substrate has a temperature uniformity of 0.2% or less,
wherein the VCSEL device has a maximum separation distance of the micro-emitter array of 0.1 [symbol] and a size of the electrode region smaller than 0.1 [symbol] ,
wherein the VCSEL sub-module has a separation distance of the VCSEL devices smaller than 1 [symbol] ,
wherein the VCSEL module is arranged such that the separation distance of the VCSEL sub-modules is smaller than 10 [symbol] .

15. The semiconductor device manufacturing apparatus of claim 12,
wherein the VCSEL sub-modules are independently supplied with power,
wherein light emitting intensities of the VCSEL sub-modules are individually controlled such that the flat substrate is heated to a predetermined deposition temperature using a pyrometer detecting the temperature of the flat substrate below the flat substrate.

16. The semiconductor device manufacturing apparatus of claim 12, wherein the flat substrate is rotated by a magnetic levitation method, and the flat substrate is rotated without interference from the VCSEL module during rotation.
